(19) United States
(12) Patent Application Publication
(10) Pub. No.: US 2011/0095754 A1
(43) Pub. Date: Apr. 28, 2011

(54) METHOD FOR MAKING A MAGNETIC FIELD SENSOR AND MAGNETIC FIELD SENSOR THUS OBTAINED

(75) Inventors: Laurent Morel, Villeurbanne (FR); Jean-Pierre Reyal, Eragny (FR)

(73) Assignees: UNIVERSITE CLAUDE BERNARD LYON I, Villeurbanne Cedex (FR); CENTRE NATIONAL DE LA RECHERCHE SCIENTIFIQUE, Paris Cedex (FR); ARCELORMITTAL- STAINLESS & NICKEL ALLOYS, Saint Denis (FR)

(21) Appl. No.: 12/867,613

(22) PCT Filed: Feb. 25, 2009
(86) PCT No.: PCT/FR2009/050304

§ 371 Date: Dec. 2, 2010

(30) Foreign Application Priority Data
Feb. 26, 2008 (FR) 0851207

(51) Int. Cl. G01R 33/02; H01F 41/14

(52) U.S. Cl. 324/244; 29/606

(57) ABSTRACT

A method for manufacturing a field sensor including a series of n probes, in which n>=3, each formed of a core of magnetic alloys associated with a coil. According to the invention, the method includes the steps of ensuring the deposit of cores of magnetic alloys onto a non-magnetic substrate, on at least part or the entirety of a surface corresponding to a series of n strips extending along axes (x, y, z) concurrent at an intersection and connected by an intersection region (z), before or after this deposit, cutting out the n strips in the substrate leaving them connected to the substrate by at least one attachment, assembling each strip with a coil, and folding at least one strip along a fold line perpendicular to the axis thereof.

The present invention relates to the technical area of sensors for measuring a magnetic field, or magnetometers.

The subject of the invention more particularly concerns magnetometers of flux gate or magneto-inductive type.

In the prior art, numerous forms of magnetometers are known. In general, a magnetometer comprises one or more magnetic probes each comprising a magnetic core associated with a coil. These magnetic cores are generally of narrow thickness possibly reaching 25 μm. According to one example of embodiment, the magnetic core consists of thin foils of ferromagnetic alloy with high permeability inserted in two semi-shells in alumina. These foils are held in place by means of two copper wires. After treating the assembly at high temperature to restore the magnetic properties, this alumina bobbin is used to wind a copper coil so as to obtain a probe with a priority axis of measurement. A magnetometer therefore comprises a probe or a series of probes arranged orthogonally for the vector determination of magnetic fields. Each probe is coupled with a measuring and control circuit of any known type. For example, document WO 90/04150 describes an application of a magnetometer for the measurement of the three components of the earth's magnetic field.

The manufacture of said magnetometers entails a certain number of drawbacks notably related to the various operations to make the cores and to the heat treatment of the cores. It is to be noted that while the use of another type of alloy for the core, such as an amorphous alloy, allows heat treatment to be avoided, this type of alloy is unstable. In addition, the assembly of these probes to form a multiaxial magnetometer proves to be relatively complex to carry out.

It is to be noted that it is known from patent application GB 2 386 198 to form a magnetic field detector by ensuring the assembly of thin magnetic layers cut from one same basic substrate.

The present invention aims at overcoming the disadvantages of the prior art by proposing a novel method for manufacturing a magnetic field sensor, designed to permit industrial manufacture that is relatively easy and low-cost, whilst ensuring safe, reliable assembly of the probes together. To reach this objective, the method for manufacturing a magnetic field sensor comprises a series of n probes, in which n>=3, each consisting of a core of magnetic alloys associated with a coil.

According to the invention, the method comprises the following steps:
ensuring the deposit of the cores of magnetic alloys onto a non-magnetic substrate, on at least part or the entirety of a surface corresponding to a series of n strips extending along axes concurrent at an intersection and connected together by an intersection region,
before or after this deposit, cutting the n strips in said substrate leaving them connected to the substrate by at least one attachment,
assembling each strip with a coil,
folding at least one strip along a fold line perpendicular to the axis thereof.

According to one advantageous embodiment, the method consists in removing the attachment(s) to release the sensor from the substrate.

According to one variant of embodiment of the invention, the method consists in:
cutting the core of magnetic alloys following the contour of the strips and leaving at least subsisting attachment,
optionally removing the core of magnetic alloys from the intersection region between the strips to separate the cores of magnetic alloys between the strips.
   According to one particular embodiment, the method consists in bonding at least one layer of nanocrystalline alloys or another type of magnetic alloy onto the substrate.

According to another particular embodiment, the method consists in vacuum depositing the alloy on part or the entirety of the substrate.

According to another particular embodiment, the method consists in serigraphy in the magnetic alloys in powder form coated with a polymer.

According to one variant of embodiment, the method consists in assembling each strip with a tubular coil slipped onto the strip.

According to another variant of embodiment, the method consists in assembling each strip with a flat coil.

Advantageously, the method consists in mounting a flat coil on each strip of the substrate, bonded onto the core of nanocrystalline alloys with inter-positioning of an insulator.

According to another variant of embodiment, the method consists in depositing the core of magnetic alloys on each strip with variation of width and shape following the extension direction of the strip.

According to one preferred variant of embodiment, the method consists in:
cutting out three strips, of two which extending along perpendicular axes, whilst the axis of the third strip forms an angle of about 135° with the axis of the neighbouring strip,
and in folding the third strip so that its axis of extension forms a determined angle with the plane formed by the axes of the two other strips.

A further objective of the invention is to propose a magnetic field sensor which comprises a series of n probes, in which n=3, each consisting of a core of magnetic alloys associated with a coil, the n probes comprising n strips of a common substrate connected together via an intersection region by extending along n axes concurrent at a n point of intersection.

According to one variant of embodiment the sensor, comprises, as core of magnetic alloys, at least one layer of nanocrystalline alloys bonded to a strip, or a layer of magnetic alloys deposited by thin layer vacuum depositing techniques, or a layer of magnetic composite deposited using serigraphy techniques.

According to one variant of embodiment, a tubular coil is slipped onto each strip of the substrate.

According to one variant of embodiment, a flat coil is fixed to each strip of the substrate.

Advantageously, each core of magnetic alloys has changing width and shape along the axis of extension of the strip of the associated substrate.

According to the invention, each core of magnetic alloys, relative to its centre, has a width which decreases or increases progressively and symmetrically relative to the axis of extension of the strip.

According to the invention, each core of magnetic alloys has at least one bottleneck region that is centred relative to the axis of extension of the strip; forming a saturation region for the associated probe.

Various other characteristics will become apparent from the following description given with reference to the appended drawings which, as non-limiting examples, illustrate embodiments of the subject of the invention.

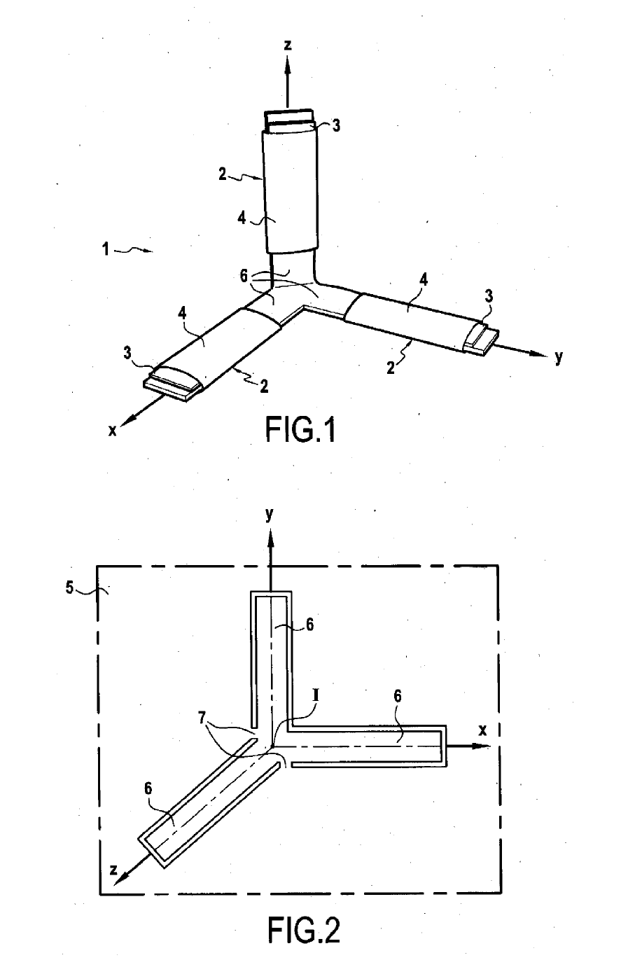

FIG. 1 is a view of an example of the forming of a magnetic field sensor conforming to the invention.

FIGS. 2 to 6 are plan views of the magnetic field sensor conforming to the invention, illustrated in different characteristic phases of manufacture.

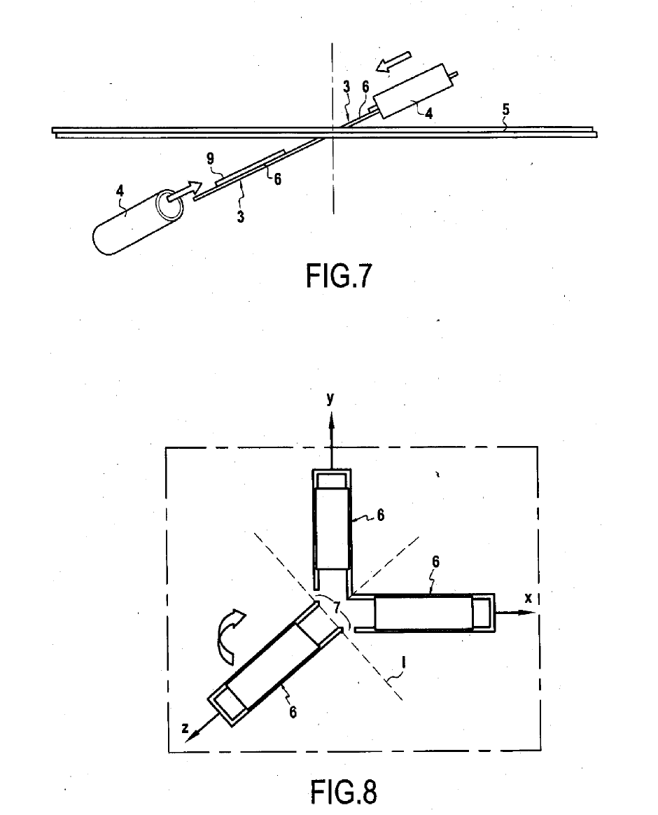

FIG. 7 is a cross-sectional, elevation view showing another characteristic step in the manufacture of the magnetic field sensor conforming to the invention.

FIG. 8 is a plan view of another step in the manufacture of the magnetic field sensor conforming to the invention.

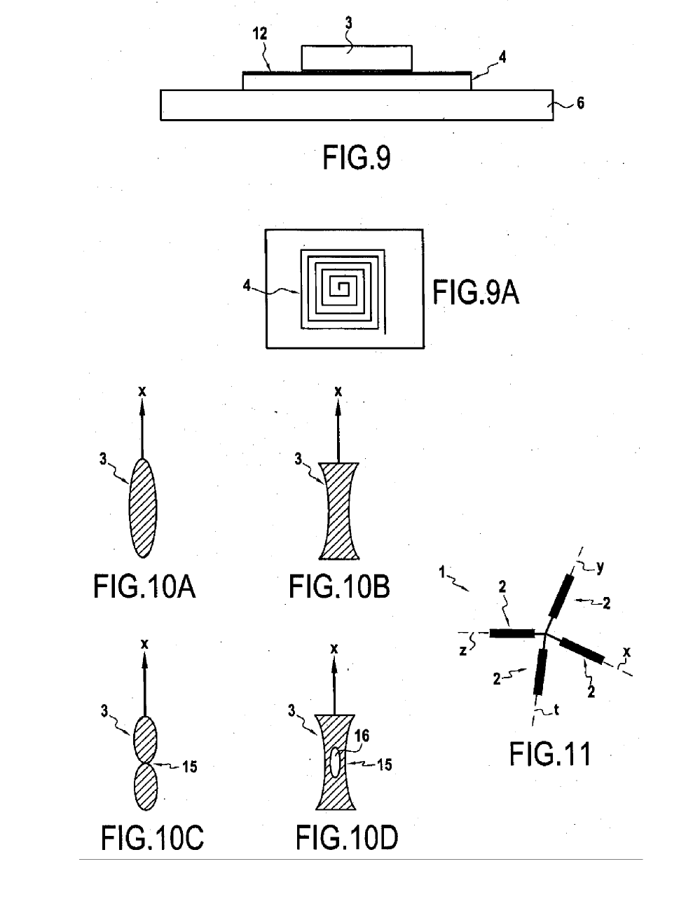

FIG. 9 illustrates a cross-sectional view of another variant of embodiment of a magnetic field sensor conforming to the invention.

FIG. 9A is an underside view of an example of embodiment of a flat coil for the sensor conforming to the invention.

FIGS. 10A to 10D illustrate different characteristic forms of embodiment of a core for a magnetic field sensor according to the invention.

FIG. 11 is a schematic of the manufacture of a magnetic field sensor conforming to the invention and comprising four probes.

As can be seen more precisely in FIG. 1, the subject of the invention concerns a magnetic field sensor 1 comprising a series of n probes 2 in which n is equal to or greater than 3. Each probe 2 comprises an axis or direction of measurement, x, y, z . . . respectively. In the example of embodiment illustrated in FIGS. 1 to 8, the magnetic field sensor 1 comprises three probes 2 with the three axes x, y, z lying orthogonal to each other. Each probe 2 comprises a core 3 of magnetic alloys associated with a coil 4.

The manufacture of said sensor 1 follows the method described below with reference to FIGS. 2 to 8.

As can be seen more clearly in FIG. 2, the method consists of cutting out in a non-magnetic substrate 5, a series of n strips 6 (in which n=3 and n=3 in the illustrated example) extending along axes x, y, z concurrent at a point of intersection I, these strips 6 being joined together by an intersection region or joint junction z. The strips 6 extending along axes x, y are offset from each other by an angle of 90°, whilst the strip 6 which extends along axis z is offset by a value of 135° relative to each strip 6 of axis x, y respectively. It is to be noted that the three strips 6 are held joined to the substrate 5 by at least one, and in the illustrated example, two attachments 7. It is to be understood that the cutting of the strips 6 is made fully around the strips with the exception of the connecting regions forming the attachments 7. The attachment(s) 7 are positioned so as to delimit one or more fold lines l for one or more strips 6.

In the illustrated example, the two attachments 7 are formed in the continuity of the strip 6 of axis z, at the junction with the two other strips 6 of axes x, y. These two attachments 7 arranged either side of the strip 6 of axis z allow the folding of this strip 6 of axis z at the junction with the two other strips 6 of axis x, y, as will be explained in the remainder hereof. For example, this non-magnetic substrate 5 is made in a non-magnetic metal substrate or preferably a thin polymer substrate. As non-magnetic metal substrate, depending on signal frequency, provision may be made to use a non-magnetic austenitic stainless steel for example or aluminium, or copper or its non-magnetic alloys. As polymer substrate, a polymer may be chosen of polyvinyl chloride type (PVC), Polyester, Polyolefin (Polyethylene, Polypropylene).

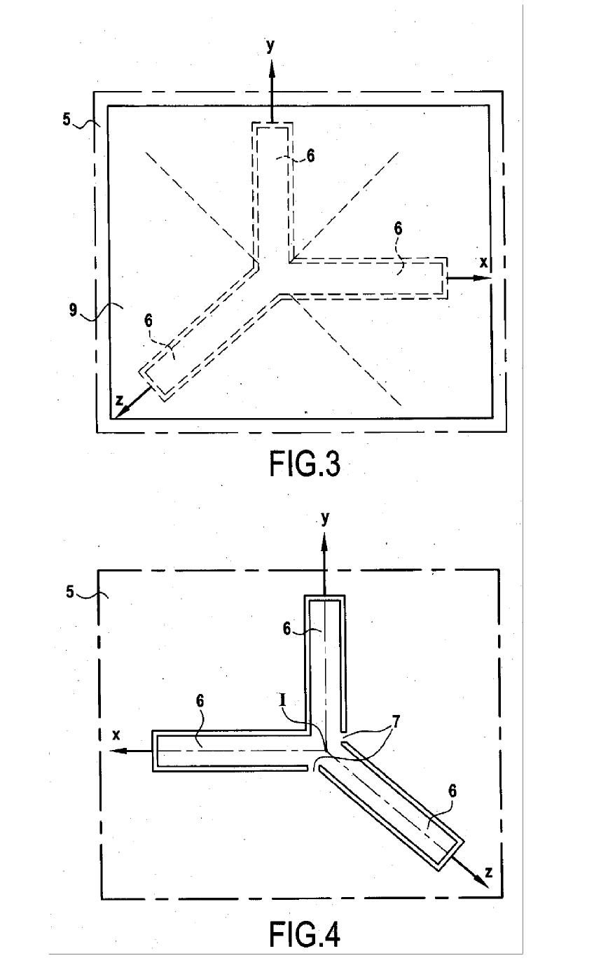

The method according to the invention consists of depositing one or more layers of magnetic alloys 9 on all or part of the strips 6 of the substrate 5 to form the core 3 of the probes. According to one preferred characteristic of the embodiment illustrated in FIG. 3, the method consists of depositing one or more thin layers of nanocrystalline alloys 9 on all the substrate 5. For example, each strip of nanocrystalline alloys is bonded to the substrate as described for example in documents WO 2005/002308 and WO 00/43556. As examples, the following alloys can be used: copper alloys, CoCrNi alloys, titanium alloys, etc. For example, each thin layer of nanocrystalline alloys has a thickness of the order of 20 μm and is separate from the substrate by a glue ensuring an electric insulating function.

Evidently, the core 3 of the probes can be fabricated using different techniques. For example, it can be envisaged to deposit one or more thin layers of magnetic alloys using vacuum evaporation depositing techniques or cathode sputtering (for example iron-nickel alloys a few μm thick). Another variant of embodiment consists of using serigraphy techniques to deposit powder magnetic alloys coated with a polymer e.g. of epoxy type.

With these different techniques, it is possible to fabricate cores of magnetic alloys 3 on all or part of the strips 6 of the different probes, which form a single piece remaining attached to the substrate 5 via the attachment(s) 7. Evidently, the depositing of the cores of magnetic alloys 3 can be performed on all or part of the surface of the substrate 5 corresponding solely to the strips 6. Evidently, this depositing can also extend to outside the strips 6, on all or part of the substrate 5.

In the example of embodiment described in connection with FIGS. 2 to 8, the depositing of the core of magnetic alloys is performed on the entire substrate 5. According to this example of embodiment, the method consists of cutting out the layer(s) of magnetic alloys 9 following the contour of the strips 6 and leaving the attachments 7 to subsist. According to one characteristic of embodiment, said cutting is conducted by a laser or micro-sanding etch operation. For this purpose, and as can be seen more clearly FIG. 4, the layer(s) of magnetic alloys 9 are etched by flipping over the substrate 5 which acts as mask.

In the description given above, the depositing of the cores of magnetic alloys 3 on the substrate 5 is performed before the cutting step of the strips 6 leaving them joined to the substrate 5 by at least one attachment 7. Evidently, the steps of depositing and cutting can be reversed. In this case the cutting step of the strips 6 leaving them attached to the substrate 5 can be conducted before the depositing step of the cores of magnetic alloys 3 on all or part of the substrate 5 and in particular on all or part of the strips 6.

The cores 3 of the strips 6 formed by the layer(s) of magnetic alloys 9 are joined together at the intersection region z of the strips 6. According to one embodiment, the probes 2 have a common core so that the layer(s) of magnetic alloys 9 formed on the different strips 6 are joined together.

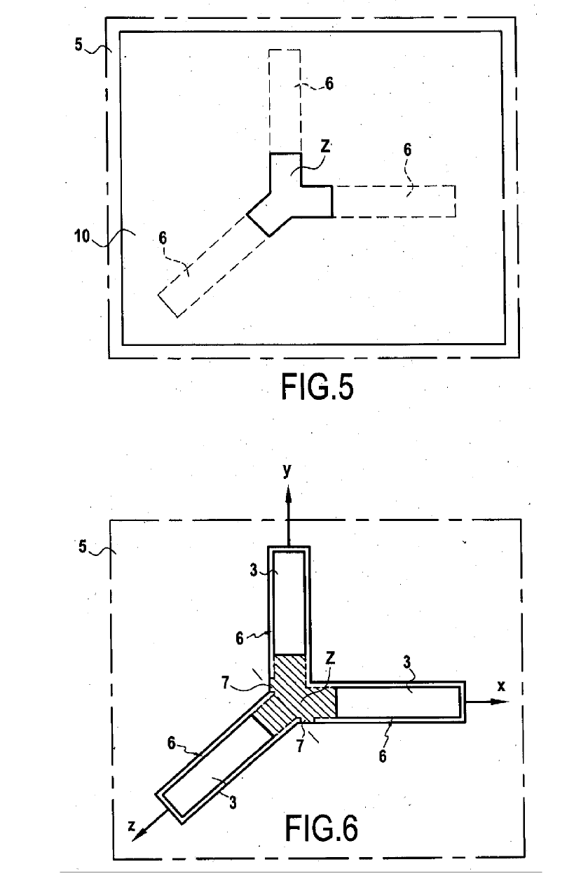

According to another embodiment, the method consists of removing the layer(s) of magnetic alloys 9 at the intersection region Z of the strips 6 to separate the layers of magnetic alloys 9 of the strips 6. In the illustrated embodiment, and as can be seen in FIG. 5, a metal cover 10 is positioned to cover all the strips 6 with the exception of the intersection region Z of the strips 6. These layers of magnetic alloys 9 are then removed by micro-sanding for example at the point where there is no metal cover 10. As can be seen more precisely in FIG. 6, three strips 6 are thereby obtained, each provided with an independent nanocrystalline core 3. The cores 3 of the strips 6 are separated from each other by the intersection region Z devoid of layers of magnetic alloys 9. Evidently, it may be envisaged to replace the metal cover by a layer of polymer or elastomer serigraphed in the regions to be protected from etching. Similarly, it may be envisaged to remove the layers of magnetic alloys 9 by chemical etching.

The method according to the invention then consists of assembling each strip 6 or core 3 with a core 4. In the example of embodiment illustrated in FIG. 7, the coil 4 is of tubular shape. According to this variant of embodiment, the strips 6 are folded around the attachments 7 to enable the threading of each coil 4 around a strip 6. Each coil 4 is thus engaged via the free end of a strip 6.

The method of the invention (as illustrated in FIG. 8) consists of ensuring the folding of at least one strip 6 along a fold line l perpendicular to its axis, so that the axis of this strip 6 lies perpendicular to the plane formed by the strips extending along the plane of the substrate 5. In the illustrated example, the strip 6 of axis z is folded along the fold line l delimited by the two attachments 7 and extending perpendicular to axis z. The strip 6 of axis z is folded at an angle of 90° relative to the plane of the substrate 5 along which the strips 6 of axes x, y extend. Insofar as the strips 6 of axis x and y are perpendicular to each other, on account of their perpendicular cutting in the common substrate 5, an assembly of three probes is obtained which lie perpendicular two by two.

After the folding operation, the attachments 7 can optionally be removed to detach the sensor from the substrate 5. Provision may effectively be made so that the sensor 1 can be used while remaining attached to the substrate 5.

In the example of embodiment illustrated in FIGS. 1 to 8, each strip 6 is associated with a tubular coil 4.

In the example illustrated in FIG. 9, each strip 6 can be associated with a flat coil 4. According to this example of embodiment, a flat coil 4 is fixed to each strip 6 of the substrate. For example, the winding 4 is etched directly on the substrate 5. The flat winding 4 can be of circular or rectangular shape as illustrated in FIG. 9A. The core of magnetic alloys 3 is fixed to the flat coil 4 with an insulator 12 inserted therebetween. The flat coil 4 and the core 3 are therefore positioned opposite or facing one another. As explained above, the core 3 can be formed of one or more layers of nanocrystalline alloys bonded to the substrate on which the flat coils 4 are formed. Evidently, the strips 6 are formed and cut using the techniques described above.

According to the example of embodiment illustrated in FIGS. 1 to 10, each core of magnetic alloys 3 has a constant width along its axis x, y, or z.

In the examples illustrated in FIGS. 10 to 10D, each core of magnetic alloys 3 has a changing width or shape along the axis of extension of the strip 6.

In the example illustrated in FIGS. 10 and 10B, each core of magnetic alloys 3, relative to its medium, respectively has a width which decreases or increases progressively and symmetrically relative to the axis of extension e.g. x of the strip. The shapes illustrated in FIGS. 10A and 10B respectively allow the anisotropy of the sensor to be increased and decreased.

According to another example of embodiment illustrated in FIGS. 10C and 10D, each core 3 has at least one bottleneck region 15 centred relative to the axis of extension x of the strip. This bottleneck region 15 forms a saturation region for the associated probe. The variants illustrated in FIGS. 10C and 10D allow the sensitivity of the probes to be increased using the cores illustrated in FIGS. 10A and 10B respectively. Saturation of the core effectively occurs at the bottleneck 15. In the examples illustrated in FIGS. 10C and 10D, the bottleneck 15 is respectively formed by a reduction in the width of the core and by forming a hole 16 in the centre of the core 3.

It follows from the preceding description that the subject of the invention allows a sensor to be fabricated which has a series of probes, suitably oriented relative to one another, with a view to determining the orientation and intensity of a magnetic field. With the method of the invention, it is possible to position the probes 2 precisely and easily relative to one another since the probes 2 are made from a single substrate 5 in which the strips are cut out 6 leaving subsisting attachments 7 which delimit at least one fold line for one strip relative to the other strips. Evidently, the sensor may comprise a different number of probes with various angles between them in relation to the envisaged applications.

For example, in the example described in connection with FIGS. 1 to 8, the sensor 1 comprises three probes 2 with three axes lying orthogonal to each other. Evidently, provision may be made so that the measurement axes of the probes have angles with each other that are different from 90° and are distributed along the three dimensions. Similarly, it may be envisaged to form a sensor with a number of probes that is higher than 3. Said solution in particular allows the sensitivity of the sensor to be increased along a priority measurement axis, by improving the calculation accuracy of the magnetic field vector.

FIG. 11 illustrates an example of embodiment of a magnetic field sensor 1 comprising four probes 2. The direction of the axes x, y, z, t of the probes 2 is chosen in relation to the application of the sensor 1. For example, to detect electric faults in an electronic power system, it is of advantage to be able to know the magnetic field in defined directions. In the example illustrated in FIG. 11, two probes 2 for example of axes x, t lie in the sample plane e.g. formed by the plane of the substrate 5 whilst the other probes of axis y, z extend outside this plane at any angle.

The invention is not limited to the described and illustrated examples since various modifications can be made thereto without departing from the scope of the invention.

1. Method for manufacturing a magnetic field sensor (1) comprising a series of n probes (2), in which n>=3, each consisting of a core of magnetic alloys (3) associated with a coil (4), characterized in that it comprises the following steps:
ensuring the deposit of cores of magnetic alloys (3) onto a non-magnetic substrate (5), on at least part or the entirety of a surface corresponding to a series of n strips (6) extending along axes (x, y, z) concurrent at an intersection and connected together by an intersection region (z),
before or after this deposit, cutting the n strips (6) in said substrate (5), leaving them connected to the substrate (5) by at least one attachment (7),
assembling each strip (6) with a coil (4),
folding at least one strip (6) along a fold line perpendicular to the axis thereof.

2. Method according to claim 1, further comprising removing the attachment(s) (7) to release the sensor from the substrate (5).

3. Method according to claim 1, further comprising:
cutting out the core of magnetic alloys (3) following the contour of the strips (6) and leaving at least one subsisting attachment (7), and
optionally removing the core of magnetic alloys (3) from the intersection region between the strips to separate the cores of magnetic alloys between the strips.

4. Method according to claim 1, characterized in that the step of depositing cores of magnetic alloys (3) comprises bonding at least one layer of nanocrystalline alloys or another type of magnetic alloy onto the substrate (5).

5. Method according to claim 1, characterized in that the step of depositing cores of magnetic alloys (3) comprises vacuum depositing the alloy on part or the entirety of the substrate (5).

6. Method according to claim 1, characterized in that the step of depositing cores of magnetic alloys (3) comprises serigraphying powder magnetic alloys coated with a polymer.

7. Method according to claim 1, further comprising assembling each strip (6) with a tubular coil (4) slipped onto the strip.

8. Method according to claim 1, further comprising assembling each strip (6) with a flat coil (4).

9. Method according to claim 8, further comprising mounting a flat coil (4) on each strip (6) of the substrate (5), bonded with inter-positioning of an insulator (12), onto the core of nanocrystalline alloys (3).

10. Method according to claim 1, further comprising depositing the core of magnetic alloys (3) on each strip (6) with variations of width and shape following in the extension direction of the strip.

11. Method according to claim 1, further comprising:
cutting out three strips (6), two of which extending along perpendicular axes (x, y) whilst axis (z) of the third strip forms an angle of about 135° with the axis of the neighbouring strip, and
folding the third strip so that its axis of extension forms a determined angle with the plane formed by the axes of the two other strips.

12. Magnetic field sensor comprising a series of n probes (2), in which n>=3, each comprising a core of magnetic alloys (3) associated with a coil (4), characterized in that the n probes comprise n strips (6) of a common substrate (5) connected together via an intersection region (z) by extending along n axes (x; y, z, t . . . ) concurrent at a n point of intersection (I).

13. Magnetic field sensor according to claim 11, characterized in that, it comprises, as core of magnetic alloys (3), at least one layer of nanocrystalline alloys bonded onto a strip (6).

14. Magnetic field sensor according to claim 11, characterized in that a tubular coil (4) is slipped onto each strip (6) of the substrate (5).

15. Magnetic field sensor according to claim 11, characterized in that a flat coil (4) is fixed to each strip (6) of the substrate (5).

16. Magnetic field sensor according to claim 11, characterized in that each core of magnetic alloys (3) has a changing width and shape along the axis of extension of the strip (6) of the associated substrate.

17. Magnetic field sensor according to claim 16, characterized in that each core of magnetic alloys (3), relative to its medium, has a width which decreases or increases progressively relative to the axis of extension of the strip.

18. Magnetic field sensor according to claim 16, characterized in that each core of magnetic alloys (3) has at least one bottleneck region (15), that is centred relative to the axis of extension of the strip, forming a saturation region for the associated probe.
